(19) United States
(12) Patent Application Publication
(10) Pub. No.: US 2007/0058415 A1
(43) Pub. Date: Mar. 15, 2007

(54) Method for depositing ferroelectric thin films using a mixed oxidant gas

(75) Inventors: Dong-Hyun Im, Suwon-si (KR); Byoung-Jae Bae, Hwaseong-si (KR); Ji-Eun Lim, Yongin-si (KR); Dong-Chul Yoo, Seongnam-si (KR); Yeon-Kyu Jung, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/520,623

(22) Filed: Sep. 14, 2006

(30) Foreign Application Priority Data
Sep. 15, 2005 (KR) 2005-86433

(51) Int. Cl. G11C 11/22

(52) U.S. Cl. 365/145

(57) ABSTRACT

Disclosed are methods of forming ferroelectric material layers introducing a plurality of metallorganic source compounds into the reaction chamber, the source compounds being supplied in an appropriate ratio for forming the ferroelectric material. These metallorganic source compounds are, in turn, reacted with a N_{y}Oₓ/O₂ oxidant gas mixture in which the N_{y}Oₓcomponent(s) represents at least 50 volume percent of the oxidant gas. This mixture of metallorganic source compounds and oxidant gas mixture(s) are maintained at a deposition temperature and deposition pressure within the reaction chamber suitable for causing a reaction between the metallorganic source compounds and the oxidant gas for a deposition period sufficient to form the ferroelectric material layer. The resulting ferroelectric material layers exhibit improved uniformity, for example, near the interface with the bottom electrode.

### PRIORITY STATEMENT

This application claims priority under 35 U.S.C. § 119 from Korean Patent Application No. 2005-86433, which was filed on Sep. 15, 2005, in the Korean Intellectual Property Office, the disclosure of which is incorporated herein, in its entirety, by reference.

### BACKGROUND

1. Field of the Disclosure

The present disclosure relates to methods of forming ferroelectric layers, capacitors incorporating such ferroelectric layers and semiconductor devices incorporating such capacitors including, for example, ferroelectric random access memory devices (also referred in the art as FRAM or FeRAM devices).

2. Background of the Art

Conventional dynamic random access memories (DRAMs) include an array of memory cells. The memory cells may assume a variety of configurations, but one common configuration includes one capacitor and one associated transistor. This configuration is sometimes referred to as a 1T-1C (or 1TC) device. Data is stored in such DRAM cells as the presence or absence of an electrical charge in the capacitor where, for example, the absence of charge in the capacitor element corresponds to a “0.” Writing data to the memory cells is accomplished by activating the associated control transistor to drain any existing charge from the capacitor or, alternatively, to supply a charge to the capacitor.

Reading data from the memory cells typically involves connecting the capacitor to a sense amplifier that detects a pulse of current if the capacitor held a charge, thereby reading a “1,” or fails to detect a pulse if the capacitor was discharged, thereby reading a “0.” Reading a DRAM cell is destructive in that the process destroys the ability of a subsequent reading to determine the unread state of the DRAM cell. Accordingly, those DRAM cells that store a “1” must be re-charged, or refreshed, before any subsequent reading may be made. Indeed, the DRAM capacitors must be refreshed periodically to ensure that a sufficient charge is present on the capacitor to indicate the presence of a “1” during a subsequent reading, thereby increasing the power consumption of such memories.

The basic construction of FRAM cells are similar to those of DRAM cells, with the notable exception that the dielectric layer used in the DRAM memory capacitors is replaced with a thin film of a ferroelectric material, for example, lead zirconate titanate.Pb(ZrₓTi₁₋ₓ)O₃, (PZT), in the FRAM cells. Other ferroelectric materials include, for example, strontium barium tantalum, SrBi₂Ta₂O₉, (SBT), strontium barium tantalum nitride, Srₓ,Bi_{2-y}(TaᵢNbⱼ)₂O_{9-z}, (SBTN), strontium barium tantalum titanate, SrₓBi₃₋ₓTa_{2-y}Ti_{y}O₉, (SBTT), SrₓBi₃₋ₓTa_{2-y}Zr_{y}O₉ (SBTZ), and bismuth lanthanum titanate, Bi₄₋ₓ LaₓTi₃O₁₂ (BLT). These example materials and other ferroelectric materials may be used singly or in combination to form the ferroelectric layer. When more than one ferroelectric material is used, the materials may be present as distinct layers achieved through sequential depositions or as composition gradients produced by altering the stoichiometry of the reactant gases continuously or in a stepwise fashion during the deposition process.

Unlike DRAM cells, however, the FRAM cells do not store a rapidly depleted electrical charge on the capacitor electrodes. Conversely, in FRAM cells application of a sufficient voltage across the ferroelectric film causes mobile atoms in the ferroelectric material to orient themselves in a similar fashion within the internal crystalline structure of the layer. These mobile atoms will remain in this orientation within the crystalline structure until reoriented by the application of a sufficient reverse voltage forces the mobile atoms to assume an alternate orientation. In FRAM memory devices, therefore, the data written to the memory cell remains reflected in the relative orientation of the mobile atoms without being continually refreshed and can reduce power consumption accordingly.

Although the physical responses differ, a FRAM device operates in a fashion similar to that of a DRAM device. Writing data to a FRAM device is accomplished by applying a field of sufficient magnitude across the ferroelectric layer by applying appropriate voltage(s) to at least one of the electrodes arranged on opposite sides of the ferroelectric layer. This programming or writing voltage forces the mobile atoms within the crystal inside into the “up” or “down” orientation (depending on the polarity of the applied voltage), thereby storing a “1” or “0” respectively. Further, this induced orientation will be maintained even if power to the FRAM device is not continuous.

Reading a FRAM cell is, however, fundamentally different than reading a DRAM cell. Rather than connecting a capacitor to a sense amplifier to determine if the capacitor was charged, reading a FRAM cell involves forcing the cell into a particular state, either a “0” or “1” and looking for a brief pulse of current associated with the reorientation of the mobile atoms in those instances in which the memory cell was in the opposite state. As with the DRAM cells, however, reading a FRAM cell destroys the stored data and requires that the cells be re-written after reading, at least in those instances in which the state was changed during the reading operation.

An advantage of FRAM devices over DRAM devices is the operation of the memory devices during the interval between the read and write cycles. In DRAM devices, the charge deposited on the capacitor plates leaks across the insulating layer and the control transistor, and may drop below a consistently readable level fairly quickly. To maintain the data within a DRAM device, every cell must be periodically read and then re-written, a process that requires a continuous supply of power and involves re-writing the entire memory array frequently, for example, every few milliseconds, whereby the majority of a DRAM device's power consumption may be used simply for refresh processing.

In contrast, FRAM devices only require power when actually reading or writing a memory cell. Accordingly, FRAM devices can exhibit power consumption levels on the order of only about one percent or even less compared with the power consumption of a similarly sized DRAM device, making FRAM devices particularly attractive for battery powered devices with long dormant periods, e.g., cell phones, digital cameras and MP3 players.

In addition to the 1T-1C (or 1TC) cell structure noted above, FRAM devices may also be configured as two transistor-two capacitor (2T-2C or 2TC) structures. However, those devices incorporating a 1TC structure utilize a unit cell consisting of one transistor and one capacitor while those incorporating a 2TC structure utilize unit cells consisting of two transistors and two capacitors. The 2TC configuration, consequently, consumes additional substrate area and tends to reduce the degree integration density that can be obtained. Accordingly, the 1TC unit cell structure is becoming more widely used to take advantage of the unit cell area reduction.

Reading operations on such FRAM devices may be performed by applying a predetermined voltage pulse to the ferroelectric capacitor electrode in a unit cell associated with a transistor via an interconnection (for example, a plate line). In fabricating highly integrated ferroelectric memories, however, the capacitance of the ferroelectric capacitors can be several orders of magnitude greater than the conventional DRAM capacitors. Accordingly, the number of FRAM cells that can be connected through a single plate line is generally limited to suppress a resistive-capacitive (RC) delay on the activating voltage pulses and maintain the operational speed of the device.

The capacitance C of a ferroelectric capacitor may be expressed by the following equation:
C=ε×A/d
wherein ε is the permittivity, A is the area of the electrode and d is the distance separating the electrodes, i.e., the thickness of the ferroelectric material layer. The electric field E that can be induced in the ferroelectric capacitor by an applied voltage V may be determined by the equation:
E=V/d.
Accordingly, in order to provide for low voltage operation and provide a large sensing margin, a smaller d, i.e., a thinner ferroelectric layer, will generally be preferred as long as the film quality remains sufficient to maintain acceptable processing and functional yields of such devices. For higher density devices, reducing the thickness of the lower electrode can reduce the footprint of the capacitor without reducing its capacity to store and maintain an adequate charge.

### SUMMARY

Example embodiments include methods of manufacturing improved ferroelectric layers, ferroelectric capacitors fabricated from such ferroelectric layers and semiconductor devices incorporating such ferroelectric capacitors, for example, FRAM devices.

An example embodiment of a method of forming such ferroelectric material layers includes introducing a carrier gas into a reaction chamber; introducing a plurality of metallorganic source compounds into the reaction chamber, the source compounds being supplied in an appropriate ratio for forming the ferroelectric material; introducing a mixed N_{y}Oₓ/oxygen oxidant gas into the reaction chamber wherein the N_{y}Oₓ component represents between 50 and 90 volume percent of the oxidant gas; and maintaining a deposition temperature and deposition pressure within the reaction chamber suitable for causing a reaction between the metallorganic source compounds and the oxidant gas for a deposition period sufficient to form the ferroelectric material layer.

Other example embodiments of methods for forming such ferroelectric material layers include methods in which the N_{y}Oₓ gas is selected from a group consisting of N₂0, NO₂ and mixtures thereof; methods in which the N_{y}Oₓ gas consists essentially of N₂O; methods in which the carrier gas is selected from a group consisting of He, N₂, Ar and mixtures thereof; methods in which the carrier gas is introduced to a reaction chamber at a volume flow rate of from 20 to 50 percent of a volume flow rate at which the oxidant gas is introduced to the reaction chamber; methods in which the ferroelectric material is selected from a group consisting of binary, tertiary and quaternary oxide and/or nitride compounds including, for example, SBT, BLT, BST, PZT, BaTiO₃, BiFeO₃, SBTN, SBTT, SBTZ. PZT, for example, may be deposited by methods in which the metallorganic source compounds include a Pb source compound, a Zr source compound and a Ti source compound that are reacted with two or more oxidizing species during a metallorganic chemical vapor deposition (MOCVD) process.

Other example embodiments of methods for forming such PZT ferroelectric material layers include methods in which the Pb source compound is selected from lead bis(2,2,6,6-tetramethyl-3,5-heptanedionate (Pb(thd)₂), lead bis(2,2,6,6-tetramethyl-3,5-heptanedionate N,N′, N″-pentamethyl diethylenetriamine (Pb(thd)₂pmdeta) and mixtures thereof; methods in which the Zr source compound is selected from zirconium tetrakis(2,2,6,6-tetramethyl-3,5-heptanedionate (Zr(thd)₄), zirconium bis(isopropoxide)bis(2,2,6,6-tetramethyl-3,5-heptanedionate (Zr(O-i-Pr)₂(thd)₂) and mixtures thereof; and methods in which the Ti source compound includes titanium bis(isopropoxide)bis(2,2,6,6-tetramethyl-3,5-heptanedionate (Ti(O-i-Pr)₂(thd)₂).

Other example embodiments methods of forming such ferroelectric material layers include practicing one or more methods according to the example embodiments on a CVD system in which the Pb source compound, the Zr source compound and the Ti source compound are provided in a common source solution; other example embodiments of CVD systems for practicing the methods may be configured whereby introducing the plurality of metallorganic source compounds into the reaction chamber includes injecting a common source solution into a vaporizer maintained at a vaporization temperature Tᵥ to form a metallorganic source gas; and adjusting the metallorganic source gas to an injection temperature Tᵢ before introducing the metallorganic source gas into the reaction chamber at the injection temperature.

Other example embodiments of CVD systems for practicing the methods may be configured whereby the common source solution includes octane as a primary solvent; the vaporization temperature Tᵥ is 180 to 200° C.; and/or the injection temperature Tᵢ is 120 to 150 [200] C. Other example embodiments of the methods for forming such ferroelectric layers may utilize a deposition temperature of 550 to 590 [650]° C. at a deposition of less than 5 [10] Torr.

Example embodiments of methods for forming ferroelectric capacitors may include forming a bottom electrode layer on a semiconductor substrate; forming a ferroelectric material layer on the bottom electrode layer by introducing a carrier gas into a reaction chamber; introducing a plurality of metallorganic source compounds into the reaction chamber, the source compounds being supplied in an appropriate ratio for forming the ferroelectric material; introducing a mixed N_{y}Oₓ/oxygen oxidant gas into the reaction chamber wherein the N_{y}Oₓ component represents between 60 and 80 volume percent of the oxidant gas; and maintaining a suitable deposition temperature and deposition pressure within the reaction chamber for a deposition period sufficient to form the desired ferroelectric material layer; forming an upper electrode layer to complete a capacitor stack; and then patterning and etching the capacitor stack to form a ferroelectric capacitor structure having sidewalls.

Other example embodiments of methods for forming ferroelectric capacitors may include forming an oxygen barrier layer between the semiconductor substrate and the bottom electrode and/or forming a buffer layer between the ferroelectric layer and the upper electrode. If present, the oxygen barrier layer may be selected from a group consisting of one or more suitable materials and combinations thereof, for example, metals and metal nitrides such as Ti, TiN, TiAlN, TaN, TaSiN and mixtures thereof. Similarly, if present, the buffer layer may be selected from a group consisting of one or more suitable materials and combinations thereof, for example, LaNiO₃, SrRuO₃, In₂Sn₂0₇, IrO₂, CaRuO₃ and mixtures thereof.

Other example embodiments of methods for forming ferroelectric capacitors may include a bottom electrode layer selected from a group consisting of Ir, IrRu, SrRuO₃/Ir, CaNiO₃, CaRuO₃ and mixtures and combinations thereof; and may also include an upper electrode layer selected from a group consisting of Ir, IrRu, SrRuO₃/Ir, CaNiO₃, LaNiO₃, CaRuO₃ and mixtures and combinations thereof. The structure of the various layers according to the example embodiments may be provided within certain ranges including, for example, a bottom electrode layer having a thickness no greater than 65 nm, for example, 30 to 40 nm.

The sidewalls of the capacitor structure may also be inclined relative to a substrate surface by an angle θ. The angle θ will typically be at least 70 degrees and may approach 90 degrees in some instances, particularly thinner layers are used in forming the capacitor stack structure. Depending on the angle θ, the resulting capacitor stack structure may exhibit a generally trapezoidal or more generally rectangular cross-section. As will be appreciated by those skilled in the art, the etch performance with respect to the various materials included in the capacitor stack structure may result in local variations from the average angle of inclination of the sidewalls of the capacitor stack structure.

Other example embodiments of methods for forming ferroelectric capacitors may include introducing a carrier gas into a reaction chamber; introducing a plurality of metallorganic source compounds into the reaction chamber, the source compounds being supplied in an appropriate ratio for forming the ferroelectric material; introducing a first mixed N_{y}Oₓ/O₂ oxidant gas into the reaction chamber wherein the N_{y}Oₓ represents between 60 and 80 percent of the oxidant gas for a first deposition period; and maintaining a first deposition temperature T_{d1} and a first deposition pressure P_{d1} within the reaction chamber for the first deposition period T₁ sufficient to form a first layer of ferroelectric material; introducing a second oxidant gas having a higher O₂ content than the first mixed oxidant gas into the reaction chamber for a second deposition period; and maintaining a second deposition temperature T_{d2} and a second deposition pressure P_{d2} within the reaction chamber for the second deposition period T₂ sufficient to form a second layer of ferroelectric material. In such example embodiments of methods for forming ferroelectric layers, the second oxidant gas may be essentially pure O₂. Also in such example embodiments of methods for forming ferroelectric layers, the second layer of ferroelectric material will include a higher concentration of a metal and oxygen than the first layer of ferroelectric material.

In one example embodiment of such a method, although the entire thickness of the ferroelectric material layer may be considered PZT, the second layer or upper regions of the ferroelectric material may exhibit a higher concentration of Pb and O than the first layer of ferroelectric material as a result of the modified deposition conditions. Similar adjustments may be made for combining compatible ferroelectric materials for tailoring the properties of the resulting ferroelectric layer with more than one ferroelectric material and/or a composition gradient(s) within a general composition of a ferroelectric material to provide, for example, regions with altered oxygen and/or nitrogen concentrations.

### BRIEF DESCRIPTION OF THE DRAWINGS

The features and scope of the disclosure will become more apparent in light of the detailed discussion of example embodiments provided below with reference to the attached drawings in which:

FIG. 1 illustrates a conventional ferroelectric capacitor construction;

FIG. 2 illustrates a tapered ferroelectric capacitor construction providing for contact to underlying structure;

FIG. 3 is a flowchart illustrating an example embodiment of a method of forming a ferroelectric capacitor;

FIGS. 4A and 4B illustrate top and cross-sectional views of a ferroelectric layer formed using a conventional O₂ oxidant gas;

FIGS. 5A and 5B illustrate top and cross-sectional views of a ferroelectric layer formed using an example embodiment of a method utilizing a mixed oxidant gas;

FIGS. 6A and 6B illustrate cross-sectional and top views of the delamination of a ferroelectric layer fabricated using a conventional O₂ oxidant gas;

FIG. 7 is a graph illustrating the polarization/electrical field (P-E) curves for three alternative constructions formed using three example embodiments of methods utilizing a mixed oxidant gas;

FIG. 8 is a graph illustrating the polarization/electrical field (P-E) curves for identical constructions formed using a conventional O₂ oxidant gas and an embodiment of the method utilizing a mixed oxidant gas;

FIG. 9 is a schematic diagram of a CVD system for practicing embodiments of the method utilizing mixed oxidant gases;

FIG. 10 is a graph illustrating the shift in the hysteresis curve, i.e., the P-E curve, associated with the selection of the oxidant composition. As reflected in FIG. 10, the use of the mixed gas oxidant increases the remanent polarization that can be achieved in the treated ferroelectric materials;

FIG. 11 is a cross-sectional view of a layer structure comprising a substrate, an ILD, a barrier layer, for example 100 Å of TiAlN, a lower electrode including 300 Å of iridium and a ferroelectric layer, 1000 Å of PZT;

FIG. 12 is a graph illustrating the results of a 100 hour lifetime evaluation during which the resulting devices are baked at 150° C. and periodically evaluated for retention. As illustrated in FIG. 12, larger structures tend to produce better polarization performance, although ferroelectric devices demonstrating a range of device sizing in combination with a PZT layer of 500 Å exhibits 75% or more retention after 100 hours; and

FIG. 13 is a graph illustrating the relative number of surface defects as a function of the bottom electrode (BE) thickness (in Å) and the type of oxidant used during the formation of the ferroelectric material layer.

As will be appreciated by those skilled in the art, these example embodiments are not intended to be exhaustive and should not, therefore, be construed as unduly limiting the scope of the disclosure. Indeed, these embodiments are provided so that this disclosure will be sufficiently thorough and complete to convey the scope of the disclosure to those skilled in the art.

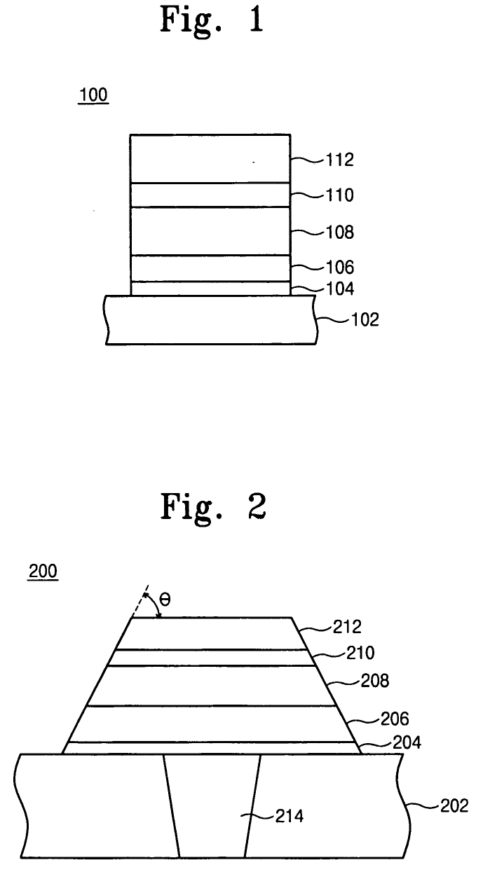

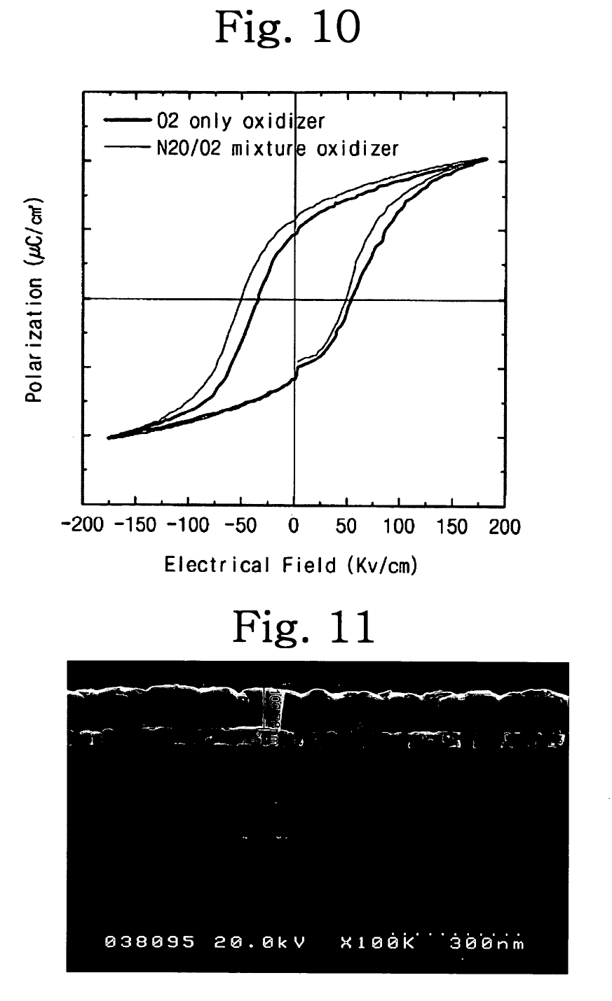

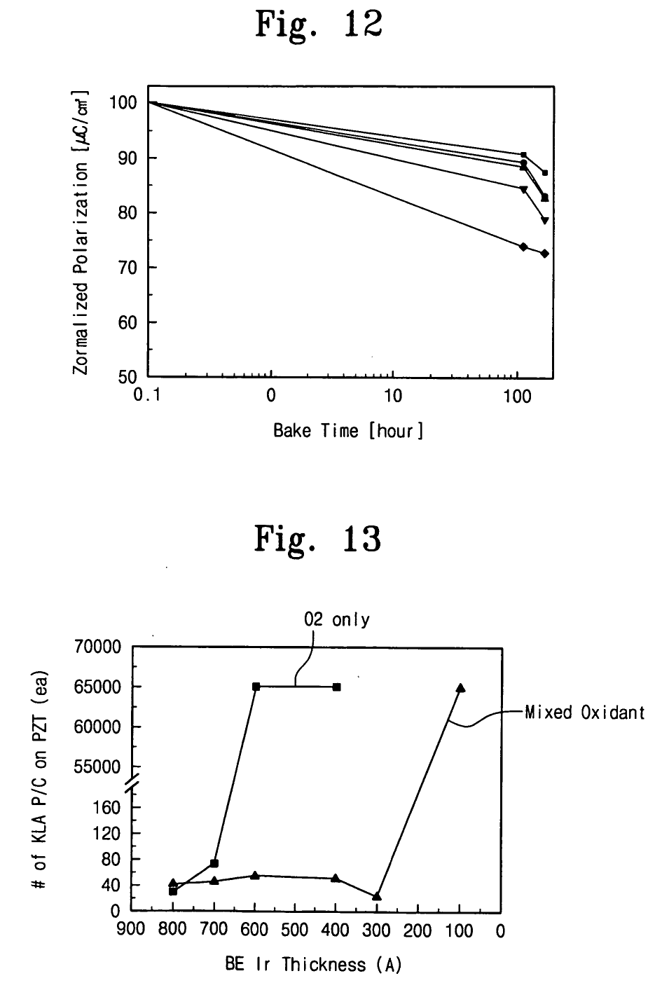

In particular, the drawings provided in FIGS. 1-13 are intended to be for illustrative purposes only and are not drawn to scale. Accordingly, the spatial relationships and relative sizing of the elements illustrated in the various embodiments, for example, the various films and layers comprising the FRAM semiconductor device may have been reduced, expanded or rearranged to improve the clarity of the figure with respect to the corresponding description. These figures, therefore, should not be interpreted as accurately reflecting the relative sizing, value or positioning of the corresponding structural elements that could be encompassed by actual semiconductor devices manufactured according to the example embodiments detailed in the disclosure.

Further, with respect to the following description, it should be understood that when a layer or an element is described as being “on” another layer or substrate, one or more intervening layers may also be present. Conversely, when a layer or an element is described as being “directly on” another layer or substrate, this language should be understood to indicate that there are no intervening materials. Further, the term “layer” will typically indicate that the referenced material is present as a continuous film formed on underlying structures or a substrate. Once portions of a layer have been removed by patterning and etching, etchback or chemical mechanical planarization processes, the remaining materials will typically be described as a “pattern.” Throughout the drawings similar numbers have been utilized to identify corresponding or like elements appearing in the various drawings, with the first digit corresponding to the number of the figure for ease of reference.

### DETAILED DESCRIPTION OF EXAMPLE EMBODIMENTS

As illustrated in FIG. 1, a conventional ferroelectric capacitor stack structure 100 includes an oxygen barrier 104, for example, a metal nitride such as TiAlN, a bottom electrode 106, for example iridium (Ir), a ferroelectric layer 108, for example PZT (Pb(ZrₓTiₓ₋₁)O₃), and an upper electrode including both a buffer layer 110, for example, a metal oxide such as SRO (SrRuO₃) and a primary conductor 112, for example, iridium. This conventional ferroelectric stack structure 100 can be formed by sequentially depositing the various layers on a substrate 102, for example, a layer of an insulating material such as silicon dioxide and then patterning and etching the resulting multilayer structure to define the individual ferroelectric capacitors required for the intended device functionality.

As illustrated in FIG. 2, a ferroelectric capacitor stack structure 200 including an oxygen barrier 204, for example, a metal nitride such as TiAlN, a bottom electrode 206, for example iridium, a ferroelectric layer 208, for example PZT (Pb(ZrₓTiₓ₋₁)O₃), and an upper electrode including both a buffer layer 210, for example, a metal oxide such as SRO (SrRuO₃) and a primary conductor 212, for example, iridium. This conventional ferroelectric stack structure 200 can be formed by sequentially depositing the various layers on a substrate 202, for example, a layer of an insulating material such as silicon dioxide, in which a buried contact structure 214 has been formed and then patterning and etching the resulting multilayer structure to define the individual ferroelectric capacitors required for the intended device functionality. The buried contact structure provides electrical contact between the bottom electrode of the ferroelectric capacitor 200 and the underlying circuitry provided on the substrate.

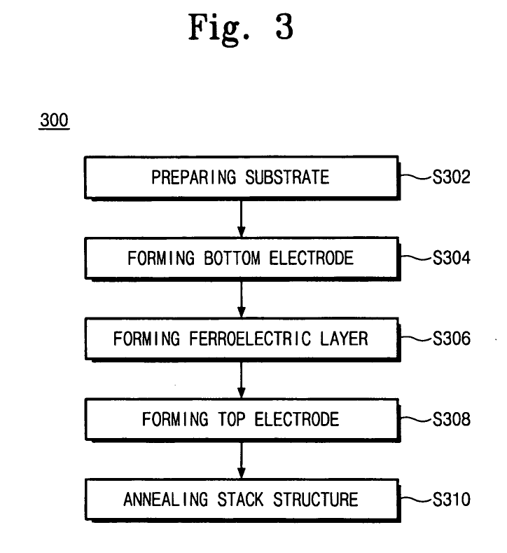

As illustrated in FIG. 3, an example embodiment of a method for forming such a ferroelectric stack structure includes preparing a suitable substrate S302, forming the bottom electrode S304, forming the ferroelectric layer(s) S306, forming a top electrode S308 and annealing the resulting structure S310. As noted above, the step of forming the bottom electrode may include forming an oxygen barrier layer between the bottom electrode and the surface of the substrate. As will be appreciated by those skilled in the art, the use of an oxygen barrier layer to suppress oxidation of the bottom electrode by oxygen from the substrate surface can help maintain the conductivity of the bottom electrode both throughout the fabrication process and during the functional life of the resulting ferroelectric devices.

As also noted above, the step of forming the top electrode may include forming a buffer layer between the ferroelectric material layer and the lower surface of the top electrode. And as will also be appreciated by those skilled in the art, the use of an buffer barrier layer may be selected to improve the resulting stack structure by, for example, improving adhesion of the top electrode and/or reducing thermal stress resulting from different thermal expansion coefficients among the various layers, both of which will tend to prove the functional life and reliability of the resulting ferroelectric devices.

An example embodiment of a method for fabricating a ferroelectric capacitor structure includes preparing a semiconductor substrate, forming an interlayer dielectric (ILD) on the semiconductor substrate, forming an oxygen barrier and/or adhesion layer on the ILD comprising, for example, Ti, TiN, TiAlN, TaN and/or TaSiN via any suitable process including, for example, CVD, ALD, PVD, sputtering, and/or E-beam evaporation. Once the barrier/adhesion layer has been formed, the bottom electrode (BE) may be formed from, for example, a noble metal, a noble metal alloy and/or a noble metal oxide including, for example, Ir, IrRu, SrRuO₃/Ir, IrO₂, CaNiO₃, CaRuO₃, and mixtures and combinations thereof. The bottom electrode may be limited to a thickness on the order of 80 nm or may be considerably thinner, for example, about 30 to 40 nm.

Once the bottom electrode has been formed, the ferroelectric material, for example a metal oxide having a Perovskite crystalline structure, can be formed using a MOCVD process that may also include forming a seed layer. After the ferroelectric material layer has been formed, a top electrode (TE) may be formed and may incorporate a two-layer structure with an initial buffer layer, for example, a metal oxide including LaNiO₃, SrRuO₃, In₂Sn₂O₇, IrO₂ and/or CaRuO₃, that is formed directly on the upper surface of the ferroelectric material and a second conducting layer, for example, a noble metal, noble metal alloy and/or oxides thereof, including, for example, Ir, IrRu, SrRuO₃/Ir, IrO₂, CaNiO₃, LaNiO₃, CaRuO₃, being, in turn, formed on the buffer layer. These layers may be formed using a variety of processes including, for example, CVD, ALD, PVD, sputtering and/or E-beam evaporation.

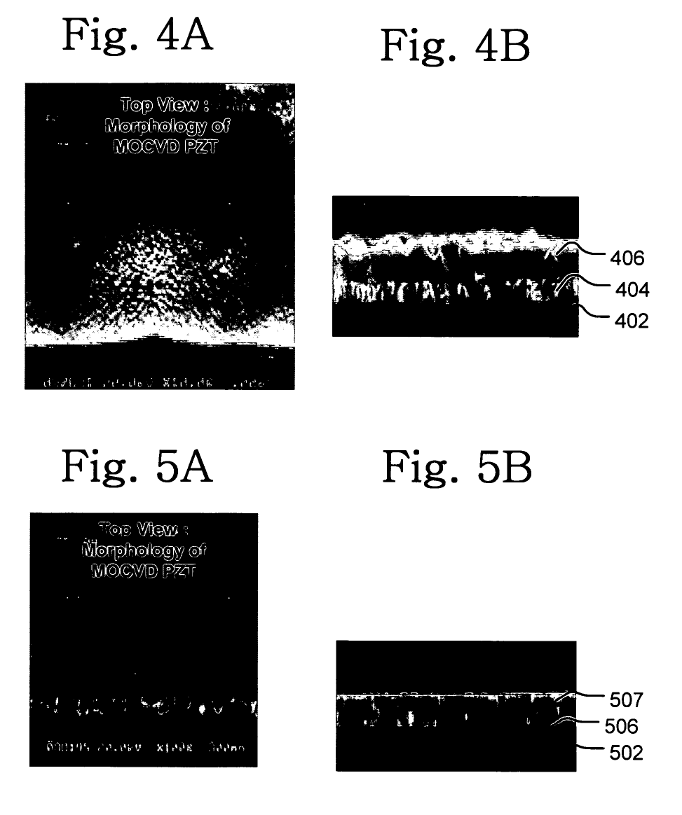

Each of the example embodiments of methods for fabricating ferroelectric material layers according to the disclosure utilize a metallorganic chemical vapor deposition (MOCVD) process for forming the ferroelectric material layer. During these processes, the metallorganic precursor compositions are reacted with an oxidant gas comprising a mixture of oxygen and at least one nitrogen/oxygen compound (N_{y}Oₓ) rather than the conventional O₂ oxidant gas. As illustrated in FIGS. 4A and 4B, when substantially pure O₂ is utilized as the oxidant gas in the conventional MOCVD process without MO sources for forming the initial layer of ferroelectric thin film on a substrate 404, the resulting initial layer 406 of ferroelectric material on the bottom electrode layer 404 has a distinctly non-uniform structure even though the MO sources don't flow.

Conversely, as illustrated in FIGS. 5A and 5B, when the initial layer of ferroelectric material is fabricated on a bottom electrode layer 506 according to an example embodiment of the methods disclosed herein utilizing a mixed oxidant gas, the resulting initial layer of ferroelectric thin film 507 exhibits improved structural uniformity throughout the thickness of the layer and specifically lacks the distinct sub-layer of abnormal ferroelectric material reflected in the corresponding FIG. 4B. These improvements in the uniformity of the ferroelectric material layer 507 translate, in turn, to improved ferroelectric performance in the resulting devices.

As noted above, the mixed oxidant gas will incorporate at least two oxidant species including O₂ and at least one nitrogen-containing oxidant gas, for example N₂O and/or NO₂, referred to generally using the formula N_{y}Oₓ, in which the nitrogen-containing oxidant gas(es) make up at least half, and more typically, the majority of the oxidant gas mixture being introduced into the reaction chamber during the MOCVD process.

An example embodiment of a method for fabricating a ferroelectric capacitor according to the method illustrated in FIG. 3 may include: preparing a suitable substrate and placing it in a reaction chamber; forming an optional oxygen barrier layer, for example, a metal, Ti, and/or a metal nitride, TiN or TiAlN on the substrate surface; forming a bottom electrode, for example, by sputtering a layer of indium having a thickness of less than about 650 Å; forming a ferroelectric material layer, for example PZT, by injecting an appropriate ratio of metallorganic precursors into the reaction chamber in combination with a combined N_{y}Oₓ/O₂ oxidant gas mixture under a combination of pressure and temperature sufficient to produce the desired deposition; forming an optional buffer layer, for example sputtering a layer of SrRuO₃ or other suitable buffer material onto the upper surface of the ferroelectric material layer; and forming a top electrode, for example, by sputtering a layer of indium.

This multilayer structure may then be patterned and etched to form the individual stacked capacitor structures. PZT has been demonstrated to provide suitable ferroelectric properties including, for example, a relatively high remanent polarization, a relatively low coercive field, but has also been associated with some less impressive performance in fatigue and retention testing.

In one example embodiment of a method for fabricating a ferroelectric capacitor using PZT the lead, zirconium and titanium metallorganic precursors may be injected into a vaporizer operating at about 190° C. to form the initial metallorganic (MO) vapor. This initial MO vapor, may be combined with a carrier gas before being transferred to the reaction chamber through heated conduits whereby the temperature of the MO vapor entering the reaction chamber is on the order of 130° C. The oxidant gas mixture may be injected into the reaction chamber at a much higher temperature, for example, 400° C., and may, for example, comprise a 2:1 mixture of the N₂O and O₂ oxidant source gases. The substrate or semiconductor wafer upon which the ferroelectric material layer will be formed may, in turn, be maintained at a deposition temperature on the order of 575° C. within the reaction chamber, for example, on a heated chuck or susceptor.

As will be appreciated by those skilled in the art, although these ratios, gases, and temperatures have been found to achieve acceptable results, it is expected that a range of values in one or more of the deposition conditions and/or the use of different metallorganic and oxidant gas combinations would still produce ferroelectric material layers that exhibit the improved uniformity achieved with the example embodiments of the method. In particular, although a 2:1 ratio is referenced above, it is expected that other gas mixtures in which the volume of the N_{y}Oₓ component equals or exceeds that of the O₂ component will provide acceptable results. For example, oxidant gas mixtures in which the value of the expression N_{y}Oₓ/(N_{y}Oₓ+O₂) (based on volume) ranges from 0.5 to 0.9 may produce acceptable results, but those in which the value of the expression ranges from 0.6 to 0.75 may produce more consistent results. Conversely, oxidant gas mixtures in which the N_{y}Oₓ is excessive, for example, N_{y}Oₓ/(N_{y}Oₓ+O₂) values above 0.8, can result in increased leakage as well.

The injection temperatures of the various reactant gases is also expected to have an impact on the quality of the resulting ferroelectric material layers. For example, although in the example above the oxidant gas mixture was injected at 400° C., it is expected that temperatures in the range of 300 to 700° C. may provide acceptable results with temperatures in the 400 to 500° C. range being expected to produce more consistent results. In most instances the pressure within the reaction chamber will be maintained at a pressure of less than 5 Torr during the deposition of the ferroelectric material layer. The metallorganic precursors may be combined with one or more carrier gases, for example, He, N₂, Ar and mixtures thereof.

For example, a 1000 Å PZT layer may be formed using lead, zirconium and titanium source flows of 117, 70 and 96 mg/minute respectively (corresponding to 0.15 sccm, 0.09 sccm and 0.12 sccm respectively), combined with an argon carrier gas at 500 sccm at 200° C. This source/carrier gas mixture is then injected into the reaction chamber with an oxidant gas stream of 1500 sccm at 400° C. through a showerhead diffuser. Additional process conditions include delivery parameters with a Vp of 190° C., a flow valve temperature FV of 130° C., a gas line temperature of 140° C. and a shower head temperature of 265° C. The chamber conditions included a wafer temperature T_{w} of 550 to 590° C., a deposition pressure of 2 Torr, and was configured to provide a shower head gap of 20 mm. Under these conditions a deposition time of just over 14 minutes (865 seconds) may be sufficient to produce a uniform PZT layer having a thickness of about 1000 Å.

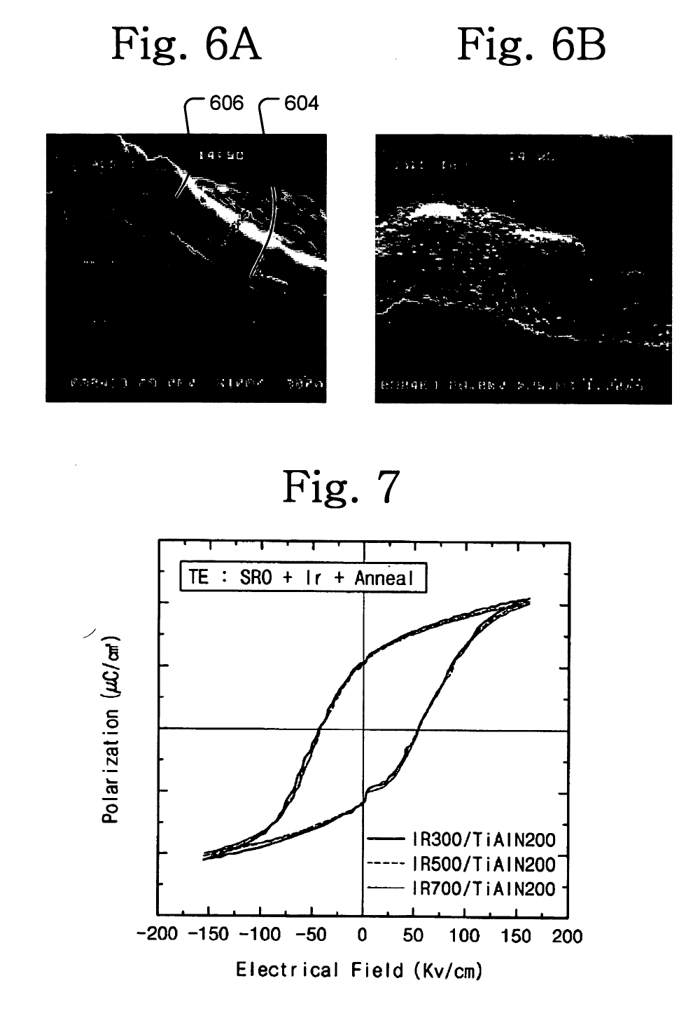

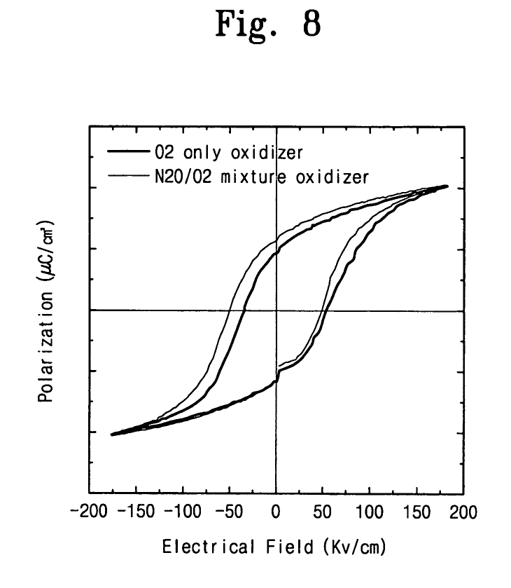

As illustrated in FIGS. 6A, 6B and 8, PZT ferroelectric material layers formed using only O₂ as the oxidant gas species tend to exhibit a range of undesirable effects including delamination of the ferroelectric material layer from the bottom electrode layer (attributed to the formation of lead silicates and/or lead oxides resulting from oxygen migrating through or being provided by the ferroelectric layer to the bottom electrode), increased leakage current, and an increased imprint on the P-E curve (FIG. 8). In order to suppress these undesirable effects, the thickness of the bottom electrode in the conventional structures is typically maintained at about 800 Å (80 nm) or greater, which, in turn, limits the range of structures that can be successfully fabricated and the degree of integration which can be maintained or achieved. Again, in addition to the illustrated delamination issues, FIG. 6A also exhibits the abnormal sub-layer 604 and the normal sub-layer 606 associated with ferroelectric material layers formed using only the conventional O₂ oxidant.

Conversely, as illustrated in FIGS. 7 and 8, similar ferroelectric capacitor structures fabricated using an oxidant gas mixture in which N_{y}Oₓ≧O₂ produces capacitors exhibiting reduced leakage current, reduced imprint on the P-E curve and reduced delamination (attributed to reduced oxygen diffusion). These improvements allow for reduced bottom electrode thickness on the order of 300 Å (30 nm) or about one third of the thickness of a conventional bottom electrode without degrading the P-E performance (FIG. 7). The ability of the methods according to the example embodiments to enable the use of thinner BE structures is further exhibited in FIG. 13, wherein the number of defects as a function of both the BE thickness and the oxidant gas used in forming the PZT layer are plotted. As reflected in FIG. 13, the mixed oxidant gas allows the use of a much thinner BE layer (300 Å as opposed to 700 Å) without generating appreciably more surface defects. This reduced bottom electrode thickness, in turn, may allow for increased stack angles (θ) that will reduce the footprint of the resulting capacitor and allow increased device integration densities and improved scalability of the resulting devices.

Reducing the thickness or “d” of the BE will tend to reduce the resistance of the BE to diffusion of the metal and oxygen components of the ferroelectric material layer, may lead to unwanted reactions involving the materials comprising the oxygen barrier and/or the ILD, and may lead to the unwanted formation of metal compounds, for example, PbSiO₃ in the case of PZT, at the oxygen barrier and within or at the ILD. Similarly, reducing the thickness of the ferroelectric material layer may result in increased leakage, reduced remanent polarization levels and reduced data retention. Accordingly, it remains the goal of those skilled in the art to balance the properties and performance of the various components of the capacitor structure and related circuitry to improve test yield and reliability of the resulting devices.

Using the mixed gas oxidant according to the example embodiments of the disclosure however, can suppress to acceptable levels or eliminate diffusion of oxygen and/or lead through the bottom electrode (BE). Indeed, it has been demonstrated that sufficient performance may be achieved with a BE having a thickness on the order of 30 nm, thus allowing for steeper sidewalls on the capacitor stack structure and improve the scalability of the resulting devices. The conventional O₂ methods, however, tended to produce devices having both increased BE thickness and a variety of performance issues, including, for example, larger leakage currents, shifted P-E curves, serve as a source for lead (Pb) and oxygen (O) diffusions into the surrounding materials and prevents increased slopes on which the methods can be practiced.

Without being bound by theory, the improvement in the ferroelectric material achieved with the addition of the nitrogen-containing oxidant gas(es) to the conventional O₂ oxidant gas may be attributed to a reduction in the formation of metal oxides (for example, Pb-O during PZT depositions, Sr-O during SBT depositions and Bi-O during BLT depositions) at or near the interface between the ferroelectric material layer and the lower electrode during the initial stage of the deposition process. These metal oxides can then later act as metal and oxygen sources for diffusion to and/or into the surrounding materials, thereby shifting or “imprinting” the P-E curve, increasing the likelihood of leakage and/or delamination of the ferroelectric material layer from the underlying materials. Conversely, by utilizing a mixed oxidant gas according to the disclosure, the interface between the BE and the ferroelectric material layer remains generally uncontaminated with metal oxides, a result perhaps achieved by suppressing formation of the suspected Pb-O compounds during the initial deposition period, thereby producing a more uniform ferroelectric material layer.

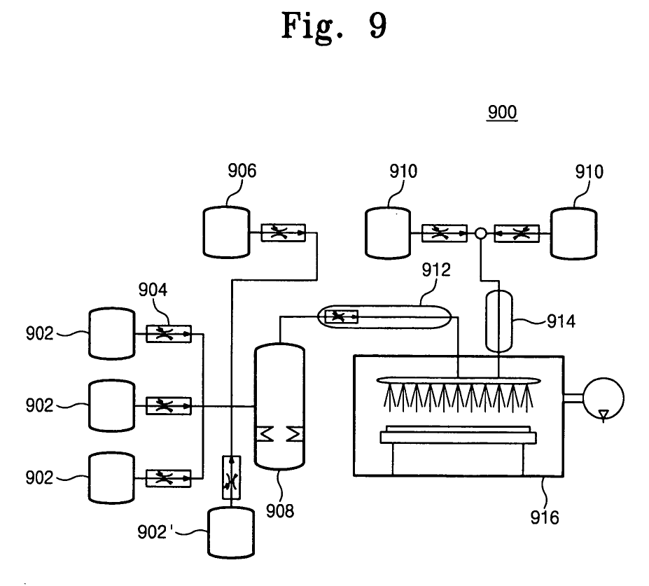

Illustrated in FIG. 9 is an example embodiment of a CVD apparatus or system 900 that may be used for practicing the methods according to the disclosure and/or fabricating ferroelectric devices according to the disclosure. As shown in FIG. 9, the various metallorganic source compounds may be maintained in separate vessels 902, or may be maintained in a generally stoichiometric mixture 902′, from which the metallorganic (MO) compounds may be fed through mass flow controllers (MFC) 904 and combined with a carrier gas or gases from 906 into a vaporizer unit 908 to form a metallorganic source vapor. This metallorganic source vapor is, in turn, fed through one or more heated conduits 912 and into a reaction chamber 916. The oxidant gases may be supplied independently from vessels 910 or combined in a single vessel to form an oxidant gas mixture having a desired N_{y}Oₓ/O₂ ratio and then heated 914 before being injected into the reaction chamber 916. Within the reaction chamber 916, the substrate and the gases will be maintained at appropriate temperatures and pressures to induce the chemical vapor deposition (CVD) of the desired ferroelectric material on the substrate.

For example, if the apparatus illustrated in FIG. 9 were being utilized for forming a PZT ferroelectric material layer, the MO compounds may include a Pb source compound selected from lead bis(2,2,6,6-tetramethyl-3,5-heptanedionate (Pb(thd)₂), lead bis(2,2,6,6-tetramethyl-3,5-heptanedionate N,N′, N″-pentamethyl diethylenetriamine (Pb(thd)₂pmdeta) and mixtures thereof; a Zr source compound selected from zirconium tetrakis(2,2,6,6-tetramethyl-3,5-heptanedionate (Zr(thd)₄), zirconium bis(isopropoxide)bis(2,2,6,6-tetramethyl-3,5-heptanedionate (Zr(O-i-Pr)₂(thd)₂) and mixtures thereof; and a Ti source compound, for example, titanium bis(isopropoxide)bis(2,2,6,6-tetramethyl-3,5-heptanedionate (Ti(O-i-Pr)₂(thd)₂).

As indicated above, if the deposition conditions remain substantially constant during the deposition process, the resulting ferroelectric material layer will tend to exhibit an improved uniformity in the thickness direction when compared with that which can be achieved using O₂ as the sole oxidant species. As a benefit of the methods according to the present example embodiments appears to be the reduction or elimination of the abnormal layer at the interface between the ferroelectric material and the bottom electrode, the use of the mixed oxidant gas may be altered throughout the progress of the deposition. For example, the initial stages of the deposition may be conducted under a mixed oxidant gas, thereby suppressing formation of the abnormal ferroelectric material, and, after the ferroelectric material has reached an intermediate thickness, switch (or being switching) the oxidant gas mixture back to substantially pure O₂, thereby increasing the oxygen content of the upper portions of the ferroelectric material layer. Accordingly, the resulting ferroelectric material layer will reflect a non-uniform composition, at least with respect to the atomic ratios of the various species, but will also tend to exhibit little or no abnormal ferroelectric material near the interface with the bottom electrode.

While example embodiments have been particularly shown and described, these embodiments are presented by way of example only and should not be understood or interpreted as unduly limiting the various structures, elements, methods and processes described above and/or illustrated in the attached Figures. That is, it will be understood by those of ordinary skill in the art that various changes in form and details may be made therein without departing from the spirit and scope of the following claims.

We claim:

1. A method of forming a ferroelectric material layer comprising:
introducing a carrier gas into a reaction chamber;
introducing a plurality of metallorganic source compounds into the reaction chamber, the source compounds being supplied in an appropriate ratio for forming the ferroelectric material;
introducing an oxidant gas mixture including a N_{y}Oₓ gas and O₂ into the reaction chamber wherein the N_{y}Oₓ gas represents between 50 and 90 volume percent of the oxidant gas; and
maintaining a deposition temperature and deposition pressure within the reaction chamber suitable for causing a reaction between the metallorganic source compounds and the oxidant gas for a deposition period sufficient to form the ferroelectric material layer.

2. The method of forming a ferroelectric material layer according to claim 1, wherein:
the N_{y}Oₓ gas is selected from a group consisting of N₂O, NO₂ and mixtures thereof.

3. The method of forming a ferroelectric material layer according to claim 1, wherein:
the N_{y}Oₓ gas consists essentially of N₂O.

4. The method of forming a ferroelectric material layer according to claim 1, wherein:
the carrier gas is selected from a group consisting of He, N₂, Ar and mixtures thereof.

5. The method of forming a ferroelectric material layer according to claim 1, wherein:
and the carrier gas is introduced to the reaction chamber at a volume flow rate of from 20 to 50 percent of a volume flow rate at which the oxidant gas is introduced to the reaction chamber.

6. The method of forming a ferroelectric material layer according to claim 1, wherein:
the ferroelectric material is selected from a group consisting of SBT, BLT, BST, PZT, BaTiO₃ and BiFeO₃.

7. The method of forming a ferroelectric material layer according to claim 6, wherein:
the ferroelectric material is PZT.

8. The method of forming a ferroelectric material layer according to claim 7, wherein:
the metallorganic source compounds include a Pb source compound, a Zr source compound and a Ti source compound.

9. The method of forming a ferroelectric material layer according to claim 8, wherein:
the Pb source compound is selected from
lead bis(2,2,6,6-tetramethyl-3,5-heptanedionate (Pb(thd)₂),
lead bis(2,2,6,6-tetramethyl-3,5-heptanedionate N,N′,
N″-pentamethyl diethylenetriamine (Pb(thd)₂pmdeta) and mixtures thereof;
the Zr source compound is selected from
zirconium tetrakis(2,2,6,6-tetramethyl-3,5-heptanedionate (Zr(thd)₄),
zirconium bis(isopropoxide)bis(2,2,6,6-tetramethyl-3,5-heptanedionate (Zr(O-i-Pr)₂(thd)₂) and mixtures thereof; and
the Ti source compound includes
titanium bis(isopropoxide)bis(2,2,6,6-tetramethyl-3,5-heptanedionate (Ti(O-i-Pr)₂(thd)₂).

10. The method of forming a ferroelectric material layer according to claim 8, wherein:
the Pb source compound, the Zr source compound and the Ti source compound are provided in a common source solution; and
wherein introducing the plurality of metallorganic source compounds into the reaction chamber includes
injecting the common source solution into a vaporizer maintained at a vaporization temperature Tᵥ to form a metallorganic source gas; and
adjusting the metallorganic source gas to an injection temperature Tᵢ and introducing the metallorganic source gas into the reaction chamber at the injection temperature.

11. The method of forming a ferroelectric material layer according to claim 10, wherein:
the common source solution includes octane as a primary solvent;
the vaporization temperature Tᵥ is 180 to 200° C.; and
the injection temperature Tᵢ is 120 to 150 [200]° C.

12. The method of forming a ferroelectric material layer according to claim 1, wherein:
the deposition temperature is 550 to 590 [650]° C.; and
the deposition pressure is less than 5 [10] Torr.

13. A method of forming a ferroelectric capacitor comprising:
forming a bottom electrode layer on a semiconductor substrate;
forming a ferroelectric material layer on the bottom electrode layer by
introducing a carrier gas into a reaction chamber;
introducing a plurality of metallorganic source compounds into the reaction chamber, the source compounds being supplied in an appropriate ratio for forming the ferroelectric material;
introducing an oxidant gas mixture including a N_{y}Oₓ gas and O₂ into the reaction chamber wherein the N_{y}Oₓ gas represents between 60 and 80 volume percent of the oxidant gas; and
maintaining a deposition temperature and deposition pressure within the reaction chamber for a deposition period sufficient to form the ferroelectric material layer;
forming an upper electrode layer to complete a capacitor stack;
patterning and etching the capacitor stack to form a ferroelectric capacitor structure having sidewalls.

14. The method of forming a ferroelectric capacitor according to claim 13, further comprising:
forming an oxygen barrier layer between the semiconductor substrate and the bottom electrode; and
forming a buffer layer between the ferroelectric layer and the upper electrode.

15. The method of forming a ferroelectric capacitor according to claim 14, wherein:
the oxygen barrier layer is selected from a group consisting of Ti, TiN, TiAlN, TaN, TaSiN, and mixtures and combinations thereof; and
the buffer layer is selected from a group consisting of LaNiO₃, SrRuO₃, In₂Sn₂O₇, IrO₂, CaRuO₃, and mixtures and combinations thereof.

16. The method of forming a ferroelectric capacitor according to claim 13, wherein:
the bottom electrode layer is selected from a group consisting of Ir, IrRu, SrRuO₃/Ir, CaNiO₃, CaRuO₃, and mixtures and combinations thereof; and
the upper electrode layer is selected from a group consisting of Ir, IrRu, SrRuO₃/Ir, CaNiO₃, LaNiO₃, CaRuO₃, and mixtures and combinations thereof.

17. The method of forming a ferroelectric capacitor according to claim 13, wherein:
the bottom electrode layer has a thickness no greater than 65 nm.

18. The method of forming a ferroelectric capacitor according to claim 13, wherein:
the bottom electrode layer has a thickness of 30 to 40 nm.

19. The method of forming a ferroelectric capacitor according to claim 13, wherein:
the sidewalls are inclined relative to a substrate surface by at least 70 degrees.

20. The method of forming a ferroelectric capacitor according to claim 19, wherein:
the sidewalls are substantially vertical relative to the substrate surface.

21. A method of forming a ferroelectric material layer comprising:
introducing a carrier gas into a reaction chamber;
introducing a plurality of metallorganic source compounds into the reaction chamber, the source compounds being supplied in an appropriate ratio for forming the ferroelectric material;
introducing an oxidant gas mixture including a N_{y}Oₓ gas and O₂ into the reaction chamber wherein the N_{y}Oₓ gas represents between 60 and 80 volume percent of the oxidant gas for a first deposition period; and
maintaining a first deposition temperature T_{d1} and a first deposition pressure P_{d1} within the reaction chamber for the first deposition period T₁ sufficient to form a first layer of ferroelectric material;
introducing a second oxidant gas having a higher O₂ content than the first mixed oxidant gas into the reaction chamber for a second deposition period; and
maintaining a second deposition temperature T_{d2} and a second deposition pressure P_{d2} within the reaction chamber for the second deposition period T₂ sufficient to form a second layer of ferroelectric material.

22. The method of forming a ferroelectric material layer according to claim 21, wherein:
the second oxidant gas is essentially pure O₂.

23. The method of forming a ferroelectric material layer according to claim 21, wherein:
the second layer of ferroelectric material includes a higher concentration of a metal and oxygen than the first layer of ferroelectric material.

24. The method of forming a ferroelectric material layer according to claim 21, wherein:
the majority of the ferroelectric material layer is PZT and the second layer of ferroelectric material a higher concentration of Pb and O than the first layer of ferroelectric material.

25. A ferroelectric capacitor structure comprising:
a bottom electrode;
a top electrode;
a ferroelectric material layer formed directly on the bottom electrode formed by reacting a plurality of metallorganic source compounds with a mixed N_{y}Oₓ/O₂ oxidant gas, wherein the ferroelectric material has a substantially uniform crystalline structure from a lower surface to an upper surface.

26. The ferroelectric capacitor structure according to claim 25, further comprising:
a buffer layer formed between the ferroelectric material layer and the top electrode.

27. The ferroelectric capacitor structure according to claim 25, wherein:
the lower electrode has a thickness of less than 40 nm.

28. The ferroelectric capacitor structure according to claim 25, wherein:
the bottom electrode consists essentially of iridium;
the ferroelectric material layer consists essentially of PZT; and
the top electrode consists essential of iridium.

29. The ferroelectric capacitor structure according to claim 26, wherein:
the buffer layer consists essentially of SrRuO₃.

30. The ferroelectric capacitor structure according to claim 28, wherein:
the ferroelectric material layer exhibits an increasing oxygen content from a lower surface to an upper surface.
